(19) United States
(12) Patent Application Publication
(10) Pub. No.: US 2005/0054134 A1
(43) Pub. Date: Mar. 10, 2005

(54) Method for manufacturing a microsystem

(76) Inventors: Wilhelm Frey, Palo Alto, CA (US); Silvia Kronmueller, Schwaikheim (DE); Christoph Duenn, Tuebingen (DE); Gary Yama, Mountain View, CA (US); Jochen Zoellin, Muellheim (DE)

Correspondence Address: KENYON & KENYON, ONE BROADWAY, NEW YORK, NY, 10004, US

(21) Appl. No.: 10/898,114

(22) Filed: Jul. 22, 2004

(30) Foreign Application Priority Data
Jul. 22, 2003 (DE) 103 33 189.1

(51) Int. Cl. H01L 21/00; H01L 21/331; H01L 21/8222

(52) U.S. Cl. 438/50; 438/52

(57) ABSTRACT

A method for manufacturing a microsystem is provided, which microsystem has a first functional layer situated on a substrate provided with an integrated circuit, the first functional layer including a conductive area and a sub-layer, and a second mechanical functional layer situated on the first functional layer. In the manufacturing method, the second mechanical functional layer is first applied to a sacrificial layer situated on the first functional layer and structured. In addition, a protective layer is provided in selected areas on the side of sub-layer facing away from the conductive area, such that as the sacrificial layer is etched, etching of the areas of the first functional layer covered by the protective layer is prevented, and in the areas of the first functional layer without the protective layer, the sub-layer is selectively etched simultaneously with the sacrificial layer, down to the conductive area.

### FIELD OF THE INVENTION

The present invention relates to a method for manufacturing a microsystem, and related more particularly to a method for manufacturing a microsystem in which a protective layer is applied to a first functional layer.

### BACKGROUND INFORMATION

An integrated microsystem may be manufactured using, among other things, silicon-germanium compounds and germanium, as described, e.g., in “Post-CMOS modular integration of poly-SiGe microstructures using poly-Ge sacrificial layers,” by A. E. Franke, Y. Jiao, T. Wu, T. J. King, R. T. Howe, Solid-State Sensor and Actuator Workshop, Hilton Head, S. C., pp. 18-21 (June 2000), and in U.S. Pat. No. 6,210,988.

Integrated microsystems are generally electronic systems or a combination of electronic and mechanical systems, e.g., resonators, acceleration sensors, or yaw rate sensors.

For the manufacture of integrated microsystems, a printed conductor layer of silicon-germanium or aluminum is first applied and structured on a wafer having electronic circuits, by means of electronic passivation. Generally, a diffusion barrier made of, e.g., titanium nitride (TiN), is located on the aluminum to prevent diffusion between the aluminum printed conductor level and a Si—Ge layer. Without this diffusion barrier, aluminum atoms would diffuse into the Si—Ge layer and possibly change the material properties of the Si—Ge layer in such a way that favorable structuring properties as well as favorable mechanical properties would be impaired.

For the structuring, a photoresist is applied to the silicon-germanium layer or the aluminum-(TiN) layer, which is subsequently light-exposed. The exposure defines the points at which the previously applied photoresist is retained. Subsequently, a development phase follows the exposure phase. Thereafter, the wafer or the silicon-germanium layer or aluminum-(TiN) layer is etched in an etching process, the unmasked parts, i.e., the parts not passivated by the exposed and developed photoresist, being removed during the etching process.

Customarily, a sacrificial layer is deposited onto the silicon-germanium layer or aluminum layer, which represents, for example, a connection between electronic and mechanical components of a microsystem, the sacrificial layer being made up, for example, of germanium or germanium-rich silicon-germanium, the latter material having a germanium content of 80%, for example. The actual Si—Ge functional layer is applied and structured via this sacrificial layer. It is possible to provide structuring of the sacrificial layer using, for example, a reactive plasma before the Si—Ge functional layer is applied. The Si—Ge functional layer has a lower germanium content than the sacrificial layer, e.g., it is possible to provide a germanium content of the Si—Ge functional layer of less than 80%. A germanium-rich Si—Ge sacrificial layer or a germanium sacrificial layer results in a Si—Ge functional layer having a lower germanium content, which is structured into the geometry of the sensor elements using an RIE method, which is generally known in the art.

After this Si—Ge functional layer is applied, the sacrificial layer is at least partially removed using an oxidant, with the following exemplary areas possibly being situated under the sacrificial layer: areas having a passivation of electronic circuits; exposed bond-pads and vias; and exposed printed conductors, which are normally made of aluminum-silicon or aluminum-silicon-copper. In the sacrificial layer etching, these metallic regions are exposed so that the metallic regions are in direct contact with the etching solution and are thus able to interact with it.

As also described in published German Patent document DE 38 74 411, hydrogen peroxide may be used as an etching solution, which does not attack the electronic passivation, for which reason no special precautions are required to protect the passivation.

However, a disadvantage of the above-described method is that when the sacrificial layers are etched, a reaction takes place between the etching solution, e.g., hydrogen peroxide, and any exposed printed conductors and bond contacts made of aluminum or aluminum alloys, which reaction may result in a partial or complete destruction of exposed metallic areas before the sacrificial layer to be eroded away is completely removed. The damage or destruction of the bond-pads or printed conductors may be equivalent to the destruction of the entire integrated microsystem. The etching attack results from the fact that when the Ge sacrificial layer or the Si—Ge sacrificial layer is dissolved, acidic reaction products are formed that reduce the pH of the H₂O₂ solution so significantly so as to shift the pH into the acidic range to such a degree that the exposed metal structures are also attacked. An approximately neutral H₂O₂ solution does not result in the undesirable etching attack on the exposed metal structures.

In order to avoid such destruction of the bond-pads or printed conductors of a microsystem, it is customary to provide the bond-pads or the printed conductors with passivation layers, which, however, require additional process steps resulting in increased manufacturing costs.

### SUMMARY

The method according to the present invention for manufacturing a microsystem provides a protective layer that is applied to a first functional layer having at least two sub-layers, i.e., a conductive area and a diffusion barrier. In this manner, the present invention achieves the advantageous result that when the sacrificial layer is removed by etching, etching of areas of the first functional layer covered by the protective layer is avoided. Furthermore, the second sub-layer representing the diffusion barrier in the exposed sections of the first functional layer is etched simultaneously with the sacrificial layer, down to the conductive area of the first functional layer.

In this connection, it is an advantage that a layer of the microsystem is conventionally provided as a protective layer on the side of the first functional layer facing the sacrificial layer as a structured etch stop layer in a plasma or sacrificial layer etching process, which means no additional deposition processes for the protective layer on the first functional layer are required.

The layer acting as a protective layer for the first functional layer during the sacrificial layer etching is structured during the manufacturing of the microsystem using the method of the present invention on the first functional layer in such a way that the areas of the first functional layer desired to be protected from the etching agent are covered by the protective layer, while remaining areas of the first functional layer are subject to an etching attack in the desired manner during the sacrificial layer etching, and in addition, the property of the protective layer as an etch stop layer is reliably ensured for the sacrificial etching process.

In this connection, it is an advantage that microsystems manufactured according to the present invention may be produced cost effectively because the step for producing the layer used according to the present invention as a protective and non-conductive layer is already included in a conventional microsystem production, and structuring of the protective layer for the present invention does not require additional deposition processes.

The protective layer provided on some areas of the first functional layer prevents etching of the diffusion-barrier sub-layer in the areas covered by the protective layer. This is of particular advantage because etching of the diffusion barrier may effectively result in a destruction of the entire microsystem because the diffusion barrier is located between the mechanical microsystem and the electronics of the microsystem, and if the diffusion barrier is removed with the microsystem anchored, the microsystem or its sub-areas are not fixedly connected to the electronics. A break-up of individual structures of the microsystem is equivalent to a total destruction of the microsystem.

Furthermore, the method of the present invention has the advantage that the conductive area of the first functional layer remaining after the etching of the sacrificial layer is structured without any additional process step. Furthermore, in selected portions of the conductive area the diffusion barrier has been removed simultaneously with the sacrificial layer, which diffusion barrier may be made of very hard materials that make it very difficult to implement wire bonding.

### BRIEF DESCRIPTION OF THE DRAWINGS

FIG. 1 shows one stage of an exemplary method for producing a microsystem according to the present invention having a substrate, an electronic circuit positioned on the substrate, a first functional layer including two sub-layers sputtered and structured onto the substrate having the electronic circuit, and a protective layer provided on the first functional layer.

FIG. 2 shows another stage of the method for producing a microsystem according to the present invention having the components shown in FIG. 1, with the addition of a sacrificial layer applied to protective layer, the sacrificial layer being structured in the same manner as the protective layer.

FIG. 3 shows another stage of the method for producing a microsystem according to the present invention having the components shown in FIG. 2, with the addition of a second structured functional layer applied to the structured sacrificial layer.

FIG. 4 shows another stage of the method for producing a microsystem according to the present invention having the components shown in FIG. 3, after the sacrificial layer has been etched.

FIG. 5 shows an enlarged detail of an exemplary embodiment of the area of the microsystem designated by “X” in FIG. 1, which area has undercuts in sidewalls of the first functional layer.

FIG. 6 shows an enlarged detail of another exemplary embodiment of the area of the microsystem designated by “X” in FIG. 1, in which area the sidewalls of the first functional layer are essentially perpendicular to the substrate.

FIG. 7 shows an enlarged detail of another exemplary embodiment of the area of the microsystem designated by “X” in FIG. 1, in which area the first functional layer has a cross-sectional profile with essentially trapezoidal sidewalls.

### DETAILED DESCRIPTION

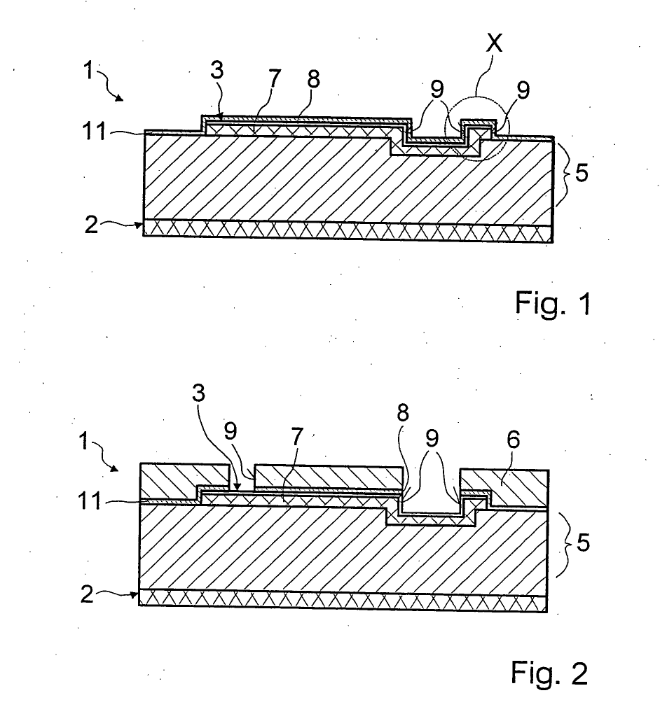

FIGS. 1 through 4 show various stages of the method for producing a microsystem 1. As shown in FIGS. 1 through 4, the microsystem 1 is made up of a substrate 2, an electronic circuit (e.g., an integrated circuit) 5 provided the substrate, a first functional layer 3, and a second functional layer 4. The first functional layer 3 includes a conductive area 7, which may be Al, AlSi, AlSiCu or the like, and a sub-layer 8, which may function as a diffusion barrier and may be formed from TiN. Accordingly, the exemplary microsystem 1 according to the present invention is a microelectromechanical system having an integrated circuit.

As an alternative to the exemplary embodiment shown in FIGS. 1-4, the sub-layer 8 of the first functional layer 3 may also be designed as multiple sub-layers and, for example, have a bonding layer and/or a contact layer applied to the side of the diffusion barrier facing away from the conductive area, the latter contact layer enhancing an electrical contact between the diffusion barrier and the second functional level by diffusion processes.

The integrated circuit, i.e., electronic circuit 5, which is shown in FIGS. 1 through 4 in a very schematic form, is situated directly on substrate 2. A mechanical system is formed partially by the second functional layer 4 which is made of silicon-germanium, for example.

Second functional layer 4 is designed to have such a low germanium content that it is not attacked by the etching solution that is used to etch sacrificial layer 6 shown in FIG. 2, which is provided between electronic circuit 5 and second functional layer 4 in the structure of microsystem 1. The germanium content of second functional layer 4 in the present case is less than 80% while the germanium content of another embodiment of the microsystem may be less than 40%, and it may assume a value between 20% and 30% in another embodiment. With such germanium contents, reactions between the etching solution, which in the case of an application to a germanium-containing sacrificial layer may contain hydrogen peroxide, and the second functional layer are reliably avoided.

Sacrificial layer 6, which is applied using an LPCVD method (low pressure chemical vapor deposition) or any other suitable method, is designed as a germanium sacrificial layer in the present case and may also have other components up to a specific proportion.

Such components may be, among other things, silicon, although a silicon content higher than an approximately 30% limiting value should be avoided in order not to prevent etching. The silicon content should be low enough so that an excessively low etching rate of sacrificial layer 6 does not negatively influence the removal of sacrificial layer 6 or the partial removal of sacrificial layer 6 during the sacrificial etching process, or result in the occurrence of silicon residues.

In the manufacture of microsystem 1, electronic circuit 5 is first produced on the substrate, i.e., on wafer 2, in a conventional manner. Thereafter, the first functional layer 3 that includes the conductive area 7 and the conductive diffusion barrier 8 situated on the conductive area 7 is applied to, and structured on, wafer 2 that has the electronic circuit 5. In the present case, conductive area 7 is designed as an aluminum layer and diffusion barrier 8 is designed as a titanium-nitride layer. After first functional layer 3 has been sputtered onto wafer 2, an organic resist is applied to first functional layer 3, the organic resist being subsequently light-exposed, developed, and thermally treated. As an alternative to this, a hard mask may also be used in place of a resist mask.

Subsequent to that, first functional layer 3 is structured using a plasma-etching method, the plasma structuring preferably being performed using a Lam Autoetch™ and using BCl₃, Cl₂, or CHCl₃ gas and preferably at a gas volume flow of 50 sccm or 30 sccm. The plasma structuring may of course also be performed using other suitable apparatuses, gases, and gas flows.

The organic resist applied before first functional layer 3 is structured and thermally treated at a temperature between 100° C. and 180° C., e.g., at a temperature of 165° C., and for such a processing time that edge areas of the resist are rounded after the thermal treatment or are at least of approximately trapezoidal shape in cross-section after the thermal treatment.

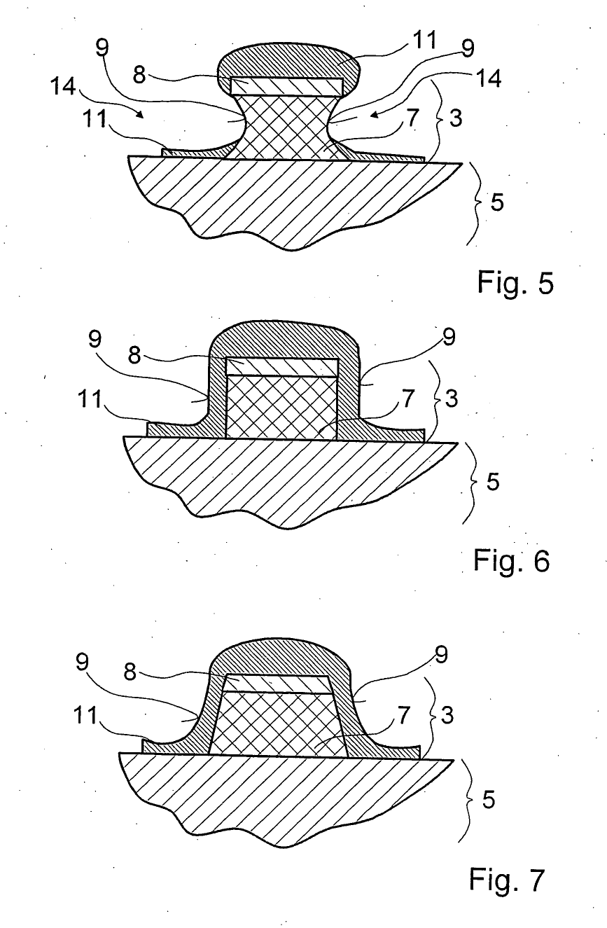

This has the result that sidewalls 9 of first functional layer 3 are also rounded or are at least of approximately trapezoidal shape in cross-section after the structuring process. The non-vertical design of sidewalls 9 of first functional layer 3 is such that an area X from FIG. 1 of microsystem 1 (shown enlarged in FIG. 7) has a trapezoidal shape in cross-section and is designed without undercuts 14 shown in FIG. 5, which prevent an adequate edge covering of functional layer 3 by a protective layer 11. This means that in area X shown in FIG. 5 starting from substrate 2 in the direction of diffusion barrier 8, microsystem 1 has a constantly diminishing layer thickness of protective layer 11, which makes an etching attack on titanium-nitride layer 8 possible in a wet-chemical structuring in the areas of first functional layer 3 not covered by protective layer 11, i.e., in the area of undercuts 14.

A sidewall geometry of structured first functional layer 3 shown in FIGS. 6 and 7 is a prerequisite for a conforming covering of first functional layer 3 by a protective layer 11, which represents an etch stop layer during the sacrificial layer etching and is designed to be electrically insulating. Protective layer 11 provides protection for first functional layer 3 during the removal of sacrificial layer 6 because protective layer 11 is not attacked by the etching agent.

Protective layer 11 is applied on structured first functional layer 3, the resist layer applied for the structuring of first functional layer 3 being removed again before protective layer 11 is applied.

The result of the sidewall geometry of first functional layer 3 having essentially trapezoidal sidewalls 9 in cross-section is that a first functional layer 3 having a thickness of, for example 700 nm, including a protective layer in the form of an SiO₂ layer, e.g., a low-temperature oxide layer (LTO layer) having a layer thickness of 100 nm, may be completely encapsulated. The quality of the encapsulation of first functional layer 3 including protective layer 11 is important in the present case in order to reliably avoid an etching of diffusion barrier 8 of first functional layer 3 when sacrificial layer 6 is removed

In another advantageous variation of the method of the present invention, sidewalls 9 of the microsystem are not rounded during the subsequent thermal treatment or do not have a trapezoidal shape in cross-section after the thermal treatment; instead, the sidewalls 9 are essentially perpendicular to the surface of first functional layer 3, as shown in FIG. 6. For first functional layer 3 to be nonetheless adequately covered in the area of sidewalls 9, protective layer 11 is designed to have a greater layer thickness than trapezoidal shaped sidewalls 9 of first functional layer 3, which, however, prolongs the deposition process time and the plasma structuring because longer etching and overetching times are necessary. Furthermore, the process reliability is decreased.

The protective layer, i.e., LTO layer 11 in the present case, is deposited onto SiH₄, e.g., at a furnace temperature of 400° C., at a process pressure of 300 mTorr, an oxygen volume flow of 135 scam, and a gas volume flow of 90 scam. Sacrificial layer 6 is then applied to protective layer 11 and structured. For structuring, sacrificial layer 6 is first coated with an organic resist, which is light-exposed, developed, and subsequently thermally treated, after which sacrificial layer 6 is structured using a plasma-etching method.

Except for the resist layer, which is applied for the structuring of first functional layer 3 and rounded by the thermal treatment, the resist layers applied for structuring the individual layers of microsystem 1 are thermally treated at a temperature from 90° C. to 130° C., e.g., 120° C., and for such a process time that the resist layers are perpendicular to the lateral surfaces under the resist layer and the volatile components are removed from the resist layers. The result is that in a subsequent structuring process such as a plasma-etching method, for example, a layer to be structured is produced having at least approximately perpendicular or vertical lateral surfaces. In this case also, a hard mask may be used as an alternative.

After sacrificial layer 6 is structured, a process in which protective layer 11 additionally represents a limiting layer for the etching process of sacrificial layer 6, some areas of protective layer 11 are removed from first functional layer 3 in a predefined manner using, for example, the same resist mask as sacrificial layer 6. Areas of protective layer 11 are removed from first functional layer 3 by a plasma etching process using SF₆ gas or CHF₃ gas, which in each case is diluted with helium in a suitable manner.

However, it is only necessary to remove protective layer 11 if protective layer 11 has not been removed or has not been completely removed during the structuring of sacrificial layer 6 in the areas of first functional layer 3, which are provided as contact surfaces for electrical terminals or electrical connections.

After the structuring of sacrificial layer 6 and, if necessary, the additionally required removal of protective layer 11 in the above-described areas of first functional layer 3, microsystem 1 is in a production stage in which microsystem 1 is only provided with exposed metal areas in those regions that will be used as anchors, bondpads, or contact pads at a later time in the production process. In the present exemplary embodiment, at this production stage, all other areas of microsystem 1 are covered by germanium sacrificial layer 6 as well as by protective layer 11 in the form of an SiO₂ layer. After sacrificial layer 6 or protective layer 11 is structured, the resist mask is again removed.

Subsequently, second functional layer 4 is applied to microsystem 1 using an LPCVD method or using another suitable method. After the deposition of second functional layer 4 in the form of a Si—Ge functional layer, an organic resist is applied to it, which is light-exposed, developed, and thermally treated at a temperature from 90° C. to 130° C., e.g., at 120° C., and for such a process time that the sidewalls of the resist layer are at least approximately vertical or perpendicular to the surface of the resist layer and the volatile components are removed from the resist layer.

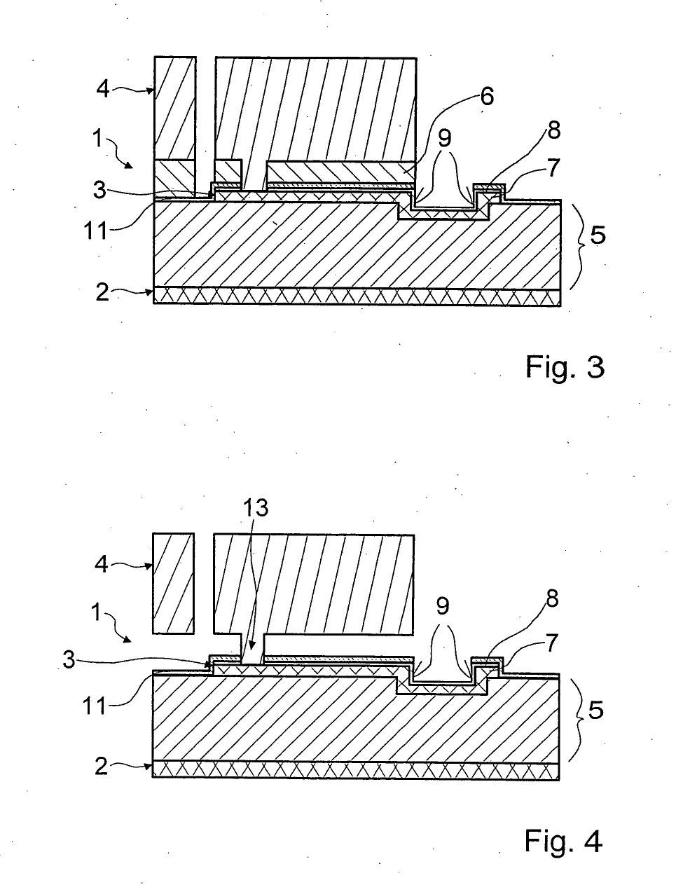

Subsequently, second functional layer 4 is structured by a plasma-etching method so that a microsystem 1 shown schematically in FIG. 3 is obtained, in which the bondpads of microsystem 1 are not covered either by second functional layer 4 and sacrificial layer 6 or by protective layer 11.

After second functional layer 4 has been structured, sacrificial layer 6 is removed. During the etching of sacrificial layer 6, the etching agent only comes into contact with diffusion barrier 8 or with exposed metal surfaces of first functional layer 3 in the area of the bondpads of microsystem 1 because the other areas of first functional layer 3 are covered either by protective layer 11 or by second functional layer 4. The areas of anchors 13 of microsystem 1, which like the bondpads have no protective layer 11, are covered by second functional layer 4 during the sacrificial layer etching and are thus shielded from the etch solution when sacrificial layer 6 is removed.

The above-described method of the present invention has the result that diffusion barrier 8 in the form of a titanium nitride layer is removed from first functional layer 3 in the area of the bondpads of microsystem 1, and aluminum layer 7 lying under it is created in a subsequent wirebond process without titanium nitride layer 8, which would otherwise make this process more difficult. In all other areas of microsystem 1, protective layer 11 shields aluminum layer 7 and diffusion barrier 8 from the etching agent used in the sacrificial layer etching so that conductive area 7, important for the function of microsystem 1, and diffusion barrier 8 of first functional level 3 are preserved.

As an alternative to the exemplary embodiment of microsystem 1 described above, the protective layer for first functional layer 3 may also be in the form of a silicon carbide layer and the sacrificial layer may be in the form of an LTO or a PECVD-SiO2 layer, which is etched using hydrofluoric acid. The general sequence of the method of the present invention is not influenced by the selection of materials for the protective layer and the sacrificial layer.

The use of hydrogen peroxide may result in etching of the aluminum layer or conductive area 7 of the first functional layer as well as diffusion barrier 8, possibly even resulting in complete destruction of the bondpads and the other exposed metal areas of the microsystem before sacrificial layer 6 is completely removed. Such effects are equivalent to the destruction of entire integrated microsystem 1.

In the present case, a maximum 30% aqueous hydrogen peroxide solution having at least an approximately neutral pH is used to remove sacrificial layer 6. In order to avoid etching an exposed aluminum pad of first functional layer 3 by the etching solution, and/or to avoid the acidic etching products formed during the etching, a buffer that maintains the pH of the etching solution during the etching process at an least approximately neutral value, i.e., at a value of approximately 7, or that adjusts the pH in a neutral range, is added to the etching solution before the etching process, because the etching solution is frequently available commercially only as an acidified solution.

In a simple manner, this avoids an etching of metallic printed conductors or metal pads, which may be made of aluminum. As an alternative, the pH of the etching solution may of course also be measured during the etching process of sacrificial layer 6 via a sensor, and if the pH of the etching solution decreases or increases significantly, the required amount of a buffer solution may be added via titration in order to adjust the pH of the etching solution to a neutral range, i.e., in a pH range between 6 and 8.

The stabilization of the pH of the etching solution by the addition of the buffer during the etching process of sacrificial layer 6 is advantageous in the case of a sacrificial layer of germanium or silicon-germanium, because etching products such as, for example, H₂Ge(OH)₆ or H₂Si(OH)₆ acidify the etching solution in an undesirable manner. Such an “acidification” of the etching solution, which would result in an etching attack on the printed conductors, and hence in destruction of the microsystem and of electronic circuit 5, is prevented by the addition of a suitable buffer.

In particular, when an etching solution of hydrogen peroxide is used, the buffer used should be at least to a large degree free of alkaline, alkaline earth, and other metals, because otherwise the hydrogen peroxide would rapidly decompose catalytically into water and oxygen due to the presence of alkaline, alkaline earth, or other metal ions. This decomposition may result in an explosion, in particular if sodium acetate or similar alkaline buffers are used. In addition, use of solutions free of alkaline, alkaline earth, and other metals should be observed in semiconductor manufacturing, because such substances contaminate production facilities and may thus result in a failure of the integrated circuits of the microelectromechanical systems manufactured in the same facilities.

As an alternative to hydrogen peroxide, it is also possible to use other suitable oxidants for etching sacrificial layer 6, the pH of which is at least approximately neutral or may be adjusted to be approximately neutral by the addition of buffers. In selecting an oxidant to be used, the pH of the oxidant represents an assumption that a suitable oxidant is stable with respect to the required, at least approximately neutral, pH. Another premise in the selection of the oxidant is that it etches titanium-nitride in the neutral pH range.

Such an oxidant may be, for example, concentrated nitric acid, because it is present in a non-dissociated form in high concentration and has no protons. When concentrated nitric acid is used, for example, an exposed aluminum pad is passivated, resulting in the prevention of an attack on exposed aluminum layer 7. Furthermore, peroxosulfate, peroxodisulfate, or chlorate may be used, the latter also, for example, as an ammonium compound in the form of ammonium chlorate, ammonium chlorite, or ammonium hypochlorite because these substances both etch and buffer.

If sacrificial layer 6 is, for example, formed from germanium or a silicon-germanium layer having a high germanium content, e.g., having a germanium content greater than 80%, the sacrificial layer is etched by the concentrated nitric acid because germanium, in contrast to aluminum, does not form a dense oxide. In any case, it should be ensured that if nitric acid is used, it is used in a concentrated form to avoid an attack of the exposed metal surfaces on the bondpads of microsystem 1.

The buffer used may be made up of compounds that include cations, for example, ammonium, tetramethyl ammonium, or tetraethyl ammonium ions. Anions corresponding to these cations and forming compounds with the aforementioned cations may include chloride, hydrogen carbonate, carbonate dihydrogen phosphate, hydrogen phosphate, phosphate, acetate, tartrate, or nitrate ions. This means that a buffer used may be a compound of the aforementioned cations and anions such as, for example, ammonium acetate, ammoniumdihydrogen phosphate, or even tetramethylammonium hydrogen phosphate.

The concentration values of the buffer used and the composition of the etching solution must be matched to the particular application, a control of the etching process being essentially a function of the oxidant in the etching solution. In the present case, a 30% aqueous hydrogen peroxide solution is described as an etching solution, which is buffered using a buffer concentration of 1% through 10% if the buffer includes one mole cations or one mole anions.

Furthermore, the use of an aforementioned buffer makes it unnecessary to add acidic components to the hydrogen peroxide frequently in order to stabilize the hydrogen peroxide, because without a buffer, the addition of the acidic components would result in a shift of the pH, which in turn would cause an etching of exposed metallic printed conductors by the etching solution during a sacrificial layer process.

Some of the above-described buffers have advantages in particular when etching germanium sacrificial layers in connection with aluminum as metal plating. Thus, when ammonium acetate in particular is used as a buffer on exposed aluminum surfaces of a microsystem, chelates or aluminum acetate layers are formed, which additionally passivate the aluminum. In addition, when ammonium acetate is used, the etching rate of the germanium is increased when etching using hydrogen peroxide.

1. A method for manufacturing a microsystem having a first functional layer and a second mechanical functional layer, the first functional layer being situated on a substrate and having a conductive layer and a sub-layer situated on the side of the conductive layer facing away from the substrate, and the second mechanical functional layer being situated on the side of the first functional layer facing away from the substrate, comprising:
applying a protective layer on the side of the sub-layer facing away from the conductive area;
applying a sacrificial layer to the first functional layer; and
applying the second mechanical functional layer to the sacrificial layer situated on the first functional layer;
wherein the protective layer functions as an etch-stop layer in a sacrificial-layer etching, and wherein the protective layer protects at least selected areas of the first functional layer, such that when the sacrificial layer is removed, etching of the selected areas of the first functional layer covered by the protective layer is prevented, and in areas of the first functional layer not protected by the protective layer, the sub-layer is selectively removed simultaneously with the sacrificial layer essentially down to the conductive area.

2. The method as recited in claim 1, wherein the sub-layer has multiple strata, and at least one of the strata is a diffusion barrier.

3. The method as recited in claim 1, wherein the microsystem further includes an electronic system, and wherein the first functional layer is electrically conductive and provides an electrical connection between the electronic system of the microsystem and a mechanical system.

4. The method as recited in claim 2, wherein the conductive area of the first functional layer is a metal layer, and the sub-layer is a TiN layer that functions as a diffusion barrier.

5. The method as recited in claim 1, wherein the protective layer is an SO₂ layer that functions as an etch-stop layer when the sacrificial layer is being one of removed and structured.

6. The method as recited in claim 5, wherein the protective layer is a low-temperature oxide layer.

7. The method as recited in claim 5, wherein the protective layer is a PECVD-SiO₂ layer.

8. The method as recited in claim 1, wherein the sacrificial layer is a Ge sacrificial layer that is removed using H₂O₂.

9. The method as recited in claim 1, wherein the protective layer is an SiC layer and the sacrificial layer is a low-temperature oxide layer, the sacrificial layer being removed using hydrofluoric acid.

10. The method as recited in claim 1, further comprising:
applying, before a component layer of the microsystem is structured, an organic resist layer to the component layer to be structured;
wherein the organic resist layer is at least one of light-exposed, developed, and thermally treated before the component layer is structured.

11. The method as recited in claim 10, wherein the thermal treatment is performed at a selected temperature and for a selected processing time such that resist areas are formed having lateral surfaces extending essentially perpendicular to the planar surface of an underlying layer of the microsystem.

12. The method as recited in claim 10, wherein the thermal treatment is performed at a temperature in the range between 90° C. and 130° C.

13. The method as recited in claim 10, wherein the resist layer is applied to the first functional layer, and wherein the thermal treatment of the resist layer is performed at a temperature in the range between 100° C. and 180° C., and wherein the processing time of the thermal treatment is selected such that edge areas of the resist layer are one of rounded and approximately trapezoidal shape in cross-section.

14. The method as recited in claim 13, wherein the first functional layer is structured in such a way that the profiles of the sidewalls of the structured first functional layer substantially correspond to the profile of the sidewall of the resist layer applied to the first functional layer for structuring.

15. The method as recited in claim 10, wherein the resist layer that has been at least one of light-exposed, developed, and thermally treated is removed before a component layer of the microsystem is applied to an already structured layer of the microsystem.

16. The method as recited in claim 4, wherein the protective layer is an SiO₂ layer that functions as an etch-stop layer when the sacrificial layer is being one of removed and structured.

17. The method as recited in claim 4, wherein the protective layer is an SiC layer and the sacrificial layer is a low-temperature oxide layer, the sacrificial layer being removed using hydrofluoric acid.

18. The method as recited in claim 9, further comprising:
applying, before a component layer of the microsystem is structured, an organic resist layer to the component layer to be structured;
wherein the organic resist layer is at least one of light-exposed, developed, and thermally treated before the component layer is structured.

19. The method as recited in claim 18, wherein the resist layer is applied to the first functional layer, and wherein the thermal treatment of the resist layer is performed at a temperature in the range between 100° C. and 180° C., and wherein the processing time of the thermal treatment is selected such that edge areas of the resist layer are one of rounded and approximately trapezoidal shape in cross-section.
